(19) United States
(12) Patent Application Publication
(10) Pub. No.: US 2015/0168238 A1
(43) Pub. Date: Jun. 18, 2015

(54) Pressure Signature Based Biometric Systems, Sensor Assemblies and Methods

(71) Applicant: MEDISENS WIRELESS, INC., Santa Clara, CA (US)

(72) Inventors: Nitin Raut, Sunnyvale, CA (US); Luke Stevens, Santa Clara, CA (US)

(73) Assignee: MEDISENS WIRELESS, INC., Santa Clara, CA (US)

(21) Appl. No.: 14/404,899

(22) PCT Filed: May 30, 2013
(86) PCT No.: PCT/US2013/043490

§ 371 Date: Dec. 1, 2014

Related U.S. Application Data
(60) Provisional application No. 61/653,071, filed on May 30, 2012.
(60) Provisional application No. 61/653,307, filed on May 30, 2012.
(60) Provisional application No. 61/653,310, filed on May 30, 2012.
(60) Provisional application No. 61/653,313, filed on May 30, 2012.
(60) Provisional application No. 61/717,032, filed on Oct. 22, 2012.

(51) Int. Cl. G01L 1/18

(52) U.S. Cl. CPC G01L 1/18

(57) ABSTRACT

The present invention is systems and methods using an array of pressure based sensors to monitor biometric information in a human patient. Data assembled and analyzed form the pressure sensor array can be compared to reference data to analyze a variety of parameters including posture, position, movement, both at individual points and over time. The assembled data is correlated to behavior, or the presence, progression, or recovery relative to a disease state. Analytical methods are disclosed for processing absolute and relative position, time, and physical data from the pressure sensor array. The sensor may be creating single plane sensor, with arbitrary layers of pressure sensitive material. These sensor configurations can be used for a variety of end uses, such as pressure sensors, moisture sensors, temperature sensors, and any kind of flexible or rigid array of one or more sensors.

### CROSS-REFERENCE TO RELATED APPLICATIONS

This application claims the benefit of U.S. Provisional Application No. 61/653,071 filed May 30, 2012 entitled “Pressure Signature Based Biometric Systems and Methods”; claims benefit of U.S. Provisional Application No. 61/653,307, filed May 30, 2012 entitled “Decoupling Using Forward/Backward Coupling”; claims benefit of U.S. Provisional Application 61/653,310, filed May 30, 2012 entitled “Wearable Sensor Assembly;” and 61/717,032, filed Oct. 22, 2012 entitled “Systems and Methods for Fluid Sensing,” which applications are hereby incorporated herein by reference in their entirety. This application is also related to PCT application PCT/US2013/043429 filed May 30, 2013, and entitled System And Method For Fluid Sensing, which application is incorporated herein by reference in its entirety.

### BACKGROUND

The use of sensors is a well known practice to gather a wide variety of data measuring a physical characteristic or parameter. Pressure sensors detect the application of physical force at a point in space. Using more than one pressure sensor creates a set or subset of data points that measure both absolute and relative pressure at each sensor location. By assembling large groups of sensors on or around an object, typically referred to as arrays, the data that is assembled from the sensors, both individually and collectively, and as assembled over time, provides a composite and more detailed picture of the physical environment of the object.

Additionally, the absolute and relative orientation of the sensors can provide a three dimensional picture and a detailed measurement of the environment in which a target object or structure exists. By continuous tracking of the sensor data, a detailed composite representation of position, orientation, and movement of the sensed object can be assembled from the data.

The advent of wireless sensors interconnected to a database and a data collection system enables remote monitoring of a target object and the sensored data, so assembled and monitored, can provide extensive information regarding the position and behavior of a target object in space and over time. By comparison to known values, both absolute and relative sensor data can be used to develop substantial information regarding a sensed object including position, movement, timing and a variety of other parameters.

Some types of pressure sensors use the measurement of strain or deflection of a sensor component to measure force applied to a particular point or region (force/area) in space. The sensor may rely on a variety of properties to measure the difference between two distinct states or conditions at the sensor. For example, a piezo-resistive effect detects strain due to applied pressure in a material and converts that strain into an electric signal. Similarly, a capacitive detector also measures strain at a point due to applied pressure. Also, the displacement of a sensor may cause changes in electrical inductance or capacitance at a selected point.

Where a sensor is formed by a conductive element, such as a thread or a wire, a point sensor may be formed by the intersection between two conductive threads or lines having known properties. Changes in the conductive properties of the lines at various points in time, together with their identification in space, can provide a combination of sensors in an array that yields information about an object in space over a series of sensor points joined together in an assembly.

Medical monitoring is frequently used to diagnose and monitor a physical condition in a patient. For example, the extent of movement, or unique movement patterns, can be a valuable parameter to measure the onset, progression, or recovery from disease. If comprehensive data sets regarding patient movement could be assembled and analyzed without the need for real time observation of a patient by a medical professional, a physician could, at low cost, assemble and review valuable information regarding the state of health of a patient and could more accurately and efficiently assess the health of the patient.

Additionally, data processing techniques can significantly improve the quality and reliability of the data collected from the sensor array. Using these techniques to refine the raw data collected from the array may mean the difference between a sensor array that is practically useful, and one that cannot gather and analyze the data with enough reliability and fidelity to be used in practice. Sensor pressure arrays that are adapted to measure features of the human body are particularly problematic because of the dynamic nature of movement exhibited by the human body. A sensor array that meaningfully and accurately measures the orientation, movement, or posture of the human form requires a large number of inputs from the sensor array. Without careful analysis and data processing, unwanted electrical currents make the data collected practically unusable. Moreover, because of the unique, dynamic, and complex nature of human physiology, data processing methods and systems are uniquely challenging when put into practice measuring the human body.

### SUMMARY OF THE INVENTION

The present invention is wireless pressure based sensors assembled in an array for patient monitoring and overall healthcare assessment. The invention includes a system for recording, assembling, and analyzing patient data developed from a plurality of sensors, usually oriented in a preselected pattern to represent a three dimensional picture of the human body or a portion thereof, or any arbitrary object that can cause pressure. The invention also includes methods of using the sensors, analyzing the data, and correlating the data to specific healthcare conditions such that the use of the pressure sensor array assembles, presents, and facilitates analysis of healthcare parameters, disease and recovery states, etc. by a healthcare professional.

The invention also includes data processing such as the use of relative and absolute values assembled from a sensor array and calculated to convey key important information regarding the position, motion, and other parameters of a patient. In specific instances, absolute and relative data from a patient, who has a pressure based sensor array associated with the body, is collected and analyzed to provide a profile of the position, movement, behavior or other parameter of the patient. In some cases, the array of sensors is oriented to mimic the three dimensional structure of the human body such that changes in the pressure measurements, both at single points in time as well as over a selected time period, can be correlated to known profiles for postures such as sitting, standing, lying, walking, and essentially, any other posture or behavior by the human body. Individual subsets as well as progressions of data over time can also be analyzed and correlated to overall levels of activity and essentially any behavioral state where measurement of the body can be detected through the use of a plurality of pressure sensors.

A sensor is formed by the intersection of two conducting lines. The sensor can use both volume and/or surface electrical characteristics, such as resistance, capacitance, or inductance to measure pressure at any particular point. The array is formed from a combination of intersections of the conducting lines, each of which forms a sensor at the point of intersection. Array may also be formed from non intersecting electrodes which may be just pairs side by side if the sensor is constructed in a single plane. See PCT/US2013/043429 specifically incorporated by reference herein. The sensor array formed from the plurality of intersections of the conducting lines can be formed into a flexible material, such as a fabric so that the sensor array can be worn by the user. Additional sensing capability can be provided by incorporating the array into a piezo-resistive fabric.

The continuous sensor array may further include a decoupling feature that yields accurate and reliable electronic and visual representations of the position, orientation or posture of the human form.

### DESCRIPTION OF THE FIGURES

FIG. 1 is a system for mapping sensor values showing a flowchart for data analysis.

FIGS. 2A and 2B are examples of data flow for possible detection using a matcher and a reference database V(ret) for identifying the posture of a patient and identifying the patient. V(res) is the result from the matcher.

FIG. 3 is a signature created from a simple sensor array showing maxima, minima, and a centroid for a representation of a data subset oriented in a simple figure using a centroid as a reference representing the human body.

FIG. 4 is a signature created using an inclination line aligned through a centroid as a reference for a representation of a data subset oriented in a simple figure as a reference representing the human body.

FIG. 5 an outline of the human body showing the contact pressure imprint with subject lying is a prone (face down) position, having representative numbers of a pressure sensor array to form an outline of the human body shape for data collection or comparison to a reference.

FIG. 6 is an outline of the human body showing how one posture covers the area on a human body, and that those dominant features or signatures can be used as pivots and/or references in a co-ordinate system. It also shows how caregivers can easily associate and interact with attached meta-data.

FIG. 7 is an alternate embodiment signature extracted from dominant feature extraction taking shape of a stick figure, which is especially useful in applications such as Identity Detection (but not limited to it)

FIG. 8 is a sensor assembly in wearable material comprised of two or more piezo resistive layers, and assembled with conductive lines traversing the layers one or more times.

FIG. 9 is a multi-layer sensor assembly. Rows are numbered R1 to Rn, Columns are numbered C1 to Cm, and the layers are numbered L1 to Lr, where n, m, and rare arbitrary integers denoting the count of each item.

FIG. 10 shows a cross section of the multilayer assembly of FIG. 9.

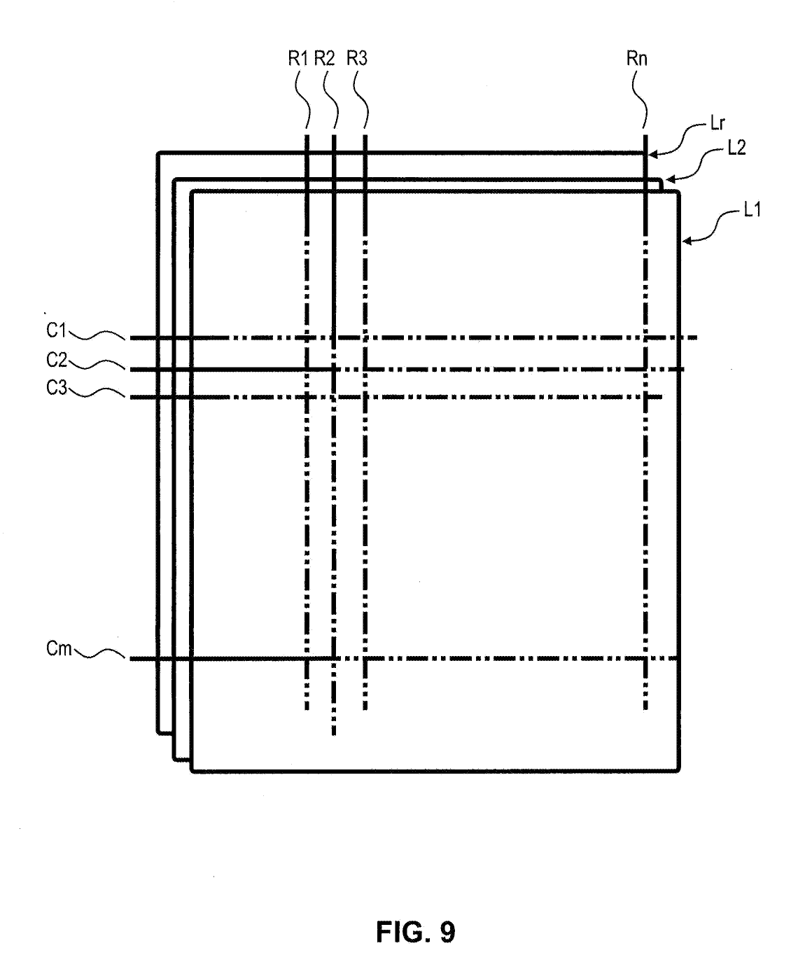

FIG. 12A shows a model of a sensor array to be used a decoupling process.

FIG. 12B shows shunt currents in a model sensor array.

FIG. 13 shows the effect of coupling on images of a human form, with varying pull-down and offset resistors.

FIG. 14 shows images of a human form, before and after decoupling the images.

### DETAILED DESCRIPTION OF THE INVENTION

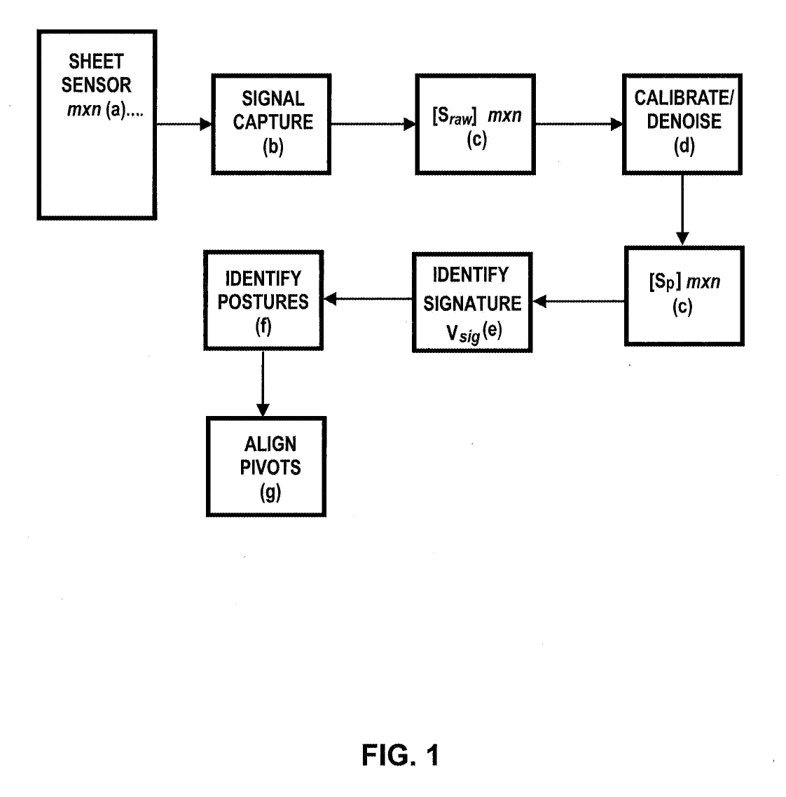

Referring to FIG. 1, a flow chart for data analysis is outlined showing a series of steps for transforming sensor data. The sensor values sensed by sheet sensor are a set of values on the sensor plane [Sraw]m×n in FIG. 1, block ‘c’. These raw values are of limited value for feeding diagnostic or analytic models. The size of this data can be quite large, e.g. if m=128, and n=64, a typical 8192 sensor array is described. If the signal is sampled at 1 Hz, a large dataset is transformed according to the method of FIG. 1. The signal is calibrated, subjected to noise removal, and option, decoupling algorithms as described below. This cleaned and calibrated signal is denoted by [Sp]m×n, and is the same size as Sraw.

This pressure signature itself can be computed by a variety of methods. The processed signal with an m×n sized array is a reasonable candidate for the signature. Some techniques for dealing with the full sized data set are discussed in US 2012/0323501 A1, which is specifically incorporated by reference herein. This full sized array generates large data sets for comparison purpose. Each point of this m×n sized frame is effectively a triple with the row and column indices into the matrix yield x, and y co-ordinates, and the value serving as a z axis.

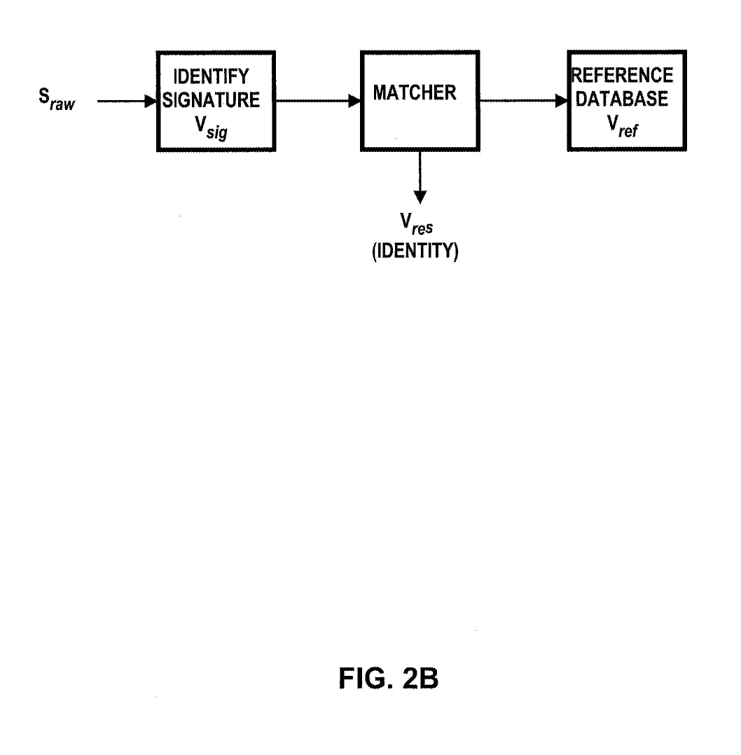

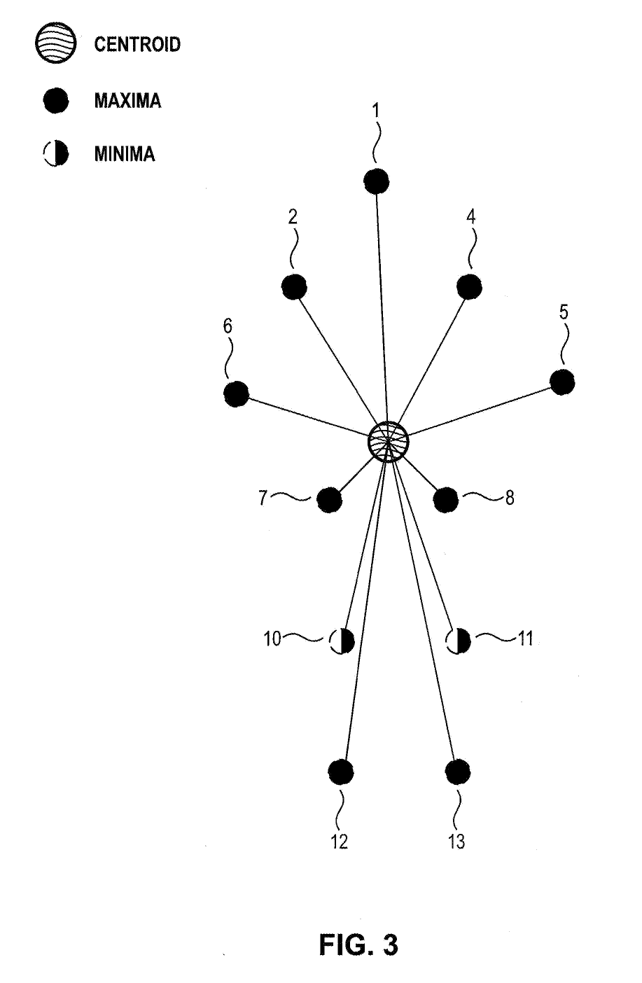

Referring to FIG. 3, The dominant feature points are those that convey most of the information about the frame. These points can be computed in a variety of ways. One simple way is by computing all the extrema (minima and maxima) on the 2 dimensional image, these extrema are computed on every row and column. This set of extrema yields a base signature. These can further be reduced by choosing dominant extrema (e.g. when maxima 1, 2, 3, 4, 5, 6, 7, 8, 12, 13 in both row and column dimensions intersect). Additionally, individual or collected data points can be calculated or be compared to a reference such as a centroid, or inclination of the body. See FIGS. 3 and 4. This vector F={1, 2, 3, 4, 5, 6, 7, 8, 10, 11, 12, 13}, in this example, is reduced from the original matrix Sp. Each of the values represents an extrema, and in its simplest form is a triple {x, y, z} where x, is column index from the original matrix Sp, y is the row index from the original matrix, z is the value. The order in the triple is not material.

Alternately, new vectors may be created for these extrema by computing the distance to a reference point. This reference point can be centroid, or inclination line, infinity, or any reference. FIG. 3 shows how the dominant feature vector can be computed using maxima 1-6, 7, 8, 12, 13, and minima 10, 11 and a centroid. The triple in the vector may be represented as {x, y, d}, where x, y are same as before and d is the distance to the centroid. Distance to the centroid, can be a 3 dimensional distance, or a projection on a 2-dimensional plane. One may create a simple single valued vector by only using the 3d distance or the distance in its projection on 2 dimensions.

FIG. 4 shows dominant features extracted using an alignment line (or inclination line) through the centroid, and then each dominant feature (1-8, 10-13) is represented as a normal distance to this line.

Using a simple preprocessor function e.g. a first order differential, etc., a wide variety of dominant feature extraction data sets are created depending on the specific application. This preprocessor function will be followed by dominant feature extraction as disclosed. Thus, the first order differential of the Sp matrix may be used to compute the dominant features.

The pressure signature thus computed can now be compared using techniques such as DTW (Dynamic Time Warping) to compute similarity measure to reference database.

Reference database is created during the data collection phase, this data is collected, and templates are created in the database for comparison purpose.

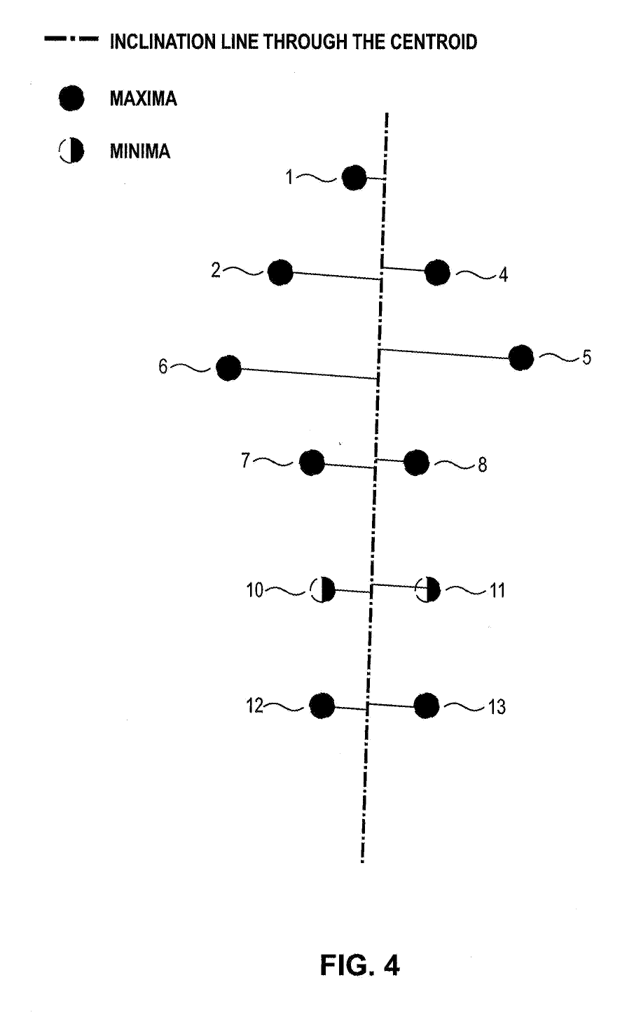

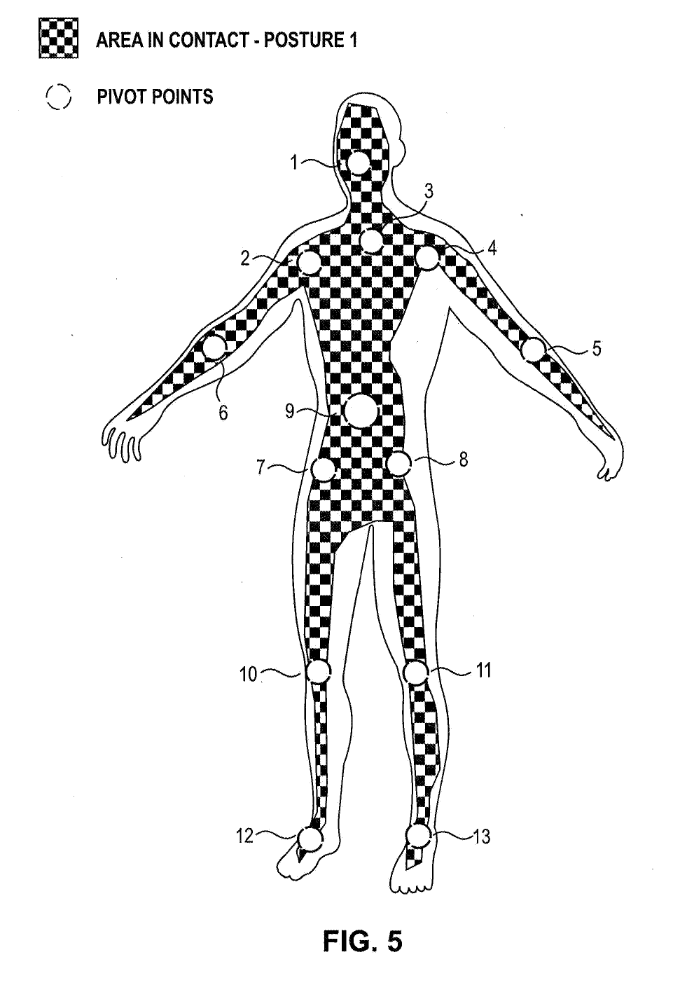

Referring to FIGS. 5 and 6, one such embodiment of the above method is either of an Identity or Posture Detection System based on pressure signature on a matrixed compound continuous sensor used to determine a biometric parameter (posture, identity, orientation, etc.). These pressure signatures can be transduced from resistance, capacitance, or inductance modulation by the incident pressure.

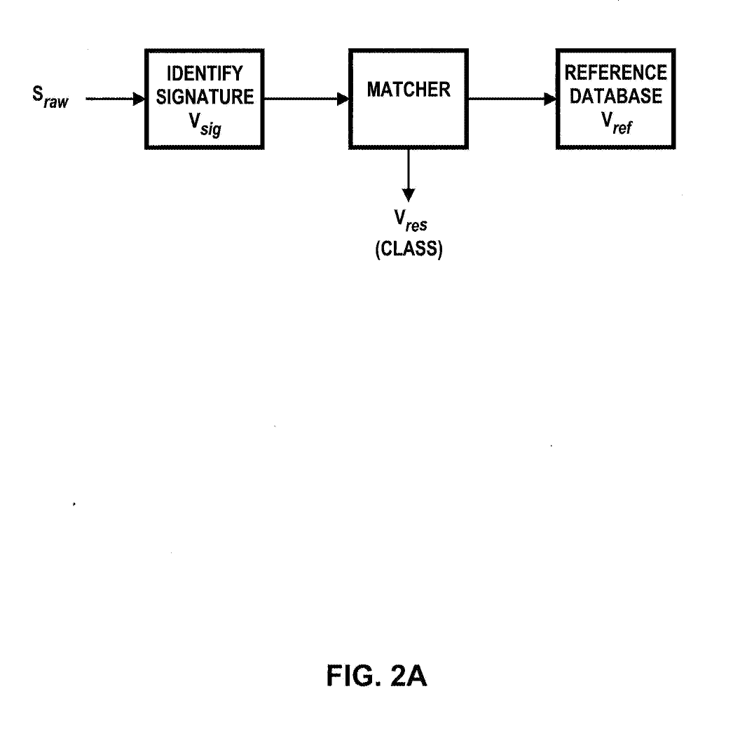

The dominant feature vector is first used to build the reference database by collecting known/desired postures from a reasonably large set of users and labeling them. This forms V_{ref}, or reference class as indicated in FIG. 2A. The signature of incoming continuous frame, is now extracted as discussed previously in extraction of pressure signature section, and matched to reference frames V_{ref}. See FIG. 2B. Vᵣₑₛ typically, is the result from the matcher, is one of labels from the closest match. For Posture detection it could be the posture; for Identity Detection it would be the identity.

A multitude of comparison measures (such as Dynamic Time Warping, K-nearest neighbor, etc.) is used to compare the incoming frame, based on known class of reference frames as shown in FIGS. 2A and 2B. The matcher then computes the closest match to the reference frames, and chooses the label (or Posture) on the closest match as the classification/detection result. The matcher is readily applied or extended to any machine learning based classifier.

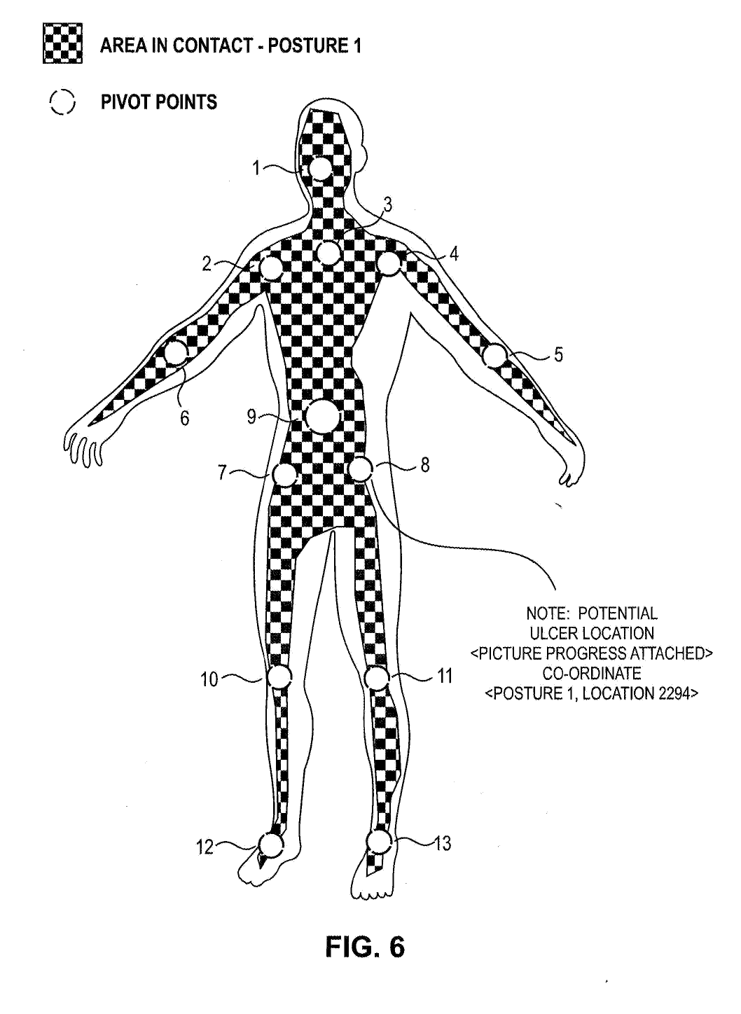

Referring to FIG. 7, a simple pressure signature can be calculated which determines all the extrema of the incident signal. These extrema, can then be made relative to a reference. The resultant vector(s) can then be used for many applications. By collecting data or through reference to a database, the reference can be selected to maximize the desirable characteristics. The centroid of a frame can be used as a reference or an alignment line can be drawn through the centroid with perpendiculars drawn to extrema points as a reference or some other reference. A set of vectors from the extrema to the reference will constitute an object by shape size, position or other representation. In a simple example, a stick figure is used as a signature to mimic the human body. A collection of data points from the stick figure will be used to compare to reference stick figure(s) to determine similarity. The signature may be comprised of a subset of extrema, or in all data points in their entirety. In this manner, a pressure signature or representation of the object of interest is assembled from biometric data.

The raw data may be a simplified representation of the object, as in the stick figure example of the human body above, or may be literally any representation that can be assembled from an array of pressure sensor data. As noted above, the data can be absolute values for position orientation or other physical characteristic or may reference a model or reference value or array for comparisons.

An object will be fully identified with 3 or more projections (at least one in every orthogonal plane). The sensed pressure distribution of an object is detected to identify the object from its pressure profile as the pressure profile will project the entire object on to the sensing plane. The necessary projections are reduced to one known or preferred position which maximizes the unique pressure signature. By reducing the number of projections, a preferred position for identifying subjects/objects is created. One or a plurality of postures may be used and in an arbitrary sequence to complete the identification or increase the accuracy of the identification.

In a system in which the subject is put into a known preferred position, the resulting pressure profile will be unique to that subject/object. The pressure signature V_{sig} can then be compared the reference database of all known subjects/objects and the identification tags on those reference signatures will allow us to determine the identity of subject/object.

Most sensors can detect incident pressure on a particular sensor on the sensor grid. The value of this data increases significantly when a plurality of values or data sets are mapped to the body, especially since the body can move over the sensor sheet. In this system, the sensed values are mapped over the subject body and tracked and assembled over time for collection in or comparison to values stored in a reference or sample database.

The identity of the pressure signature of the incoming frame is determined as described above, and particularly with respect to FIG. 3 and accompanying text.

The posture of subject is determined as described above, and particularly with respect to FIGS. 2A, 2B, 5 and 6.

Every posture creates a unique section of body experiencing the contact pressure, so the 3D body can be considered as a set of planes (or external contours). Every posture covers a certain area on the body. Referring to FIGS. 5 and 6, the pressure sensor array can be distributed across a plurality of data points that forma representation of essentially any object in space, in this case the human body. Collection of data from the pressure sensor array yields a data assembly that provides information about the position, orientation, movement, or posture of the target object.

In a co-ordinate system on the 3D human body, the co-ordinate system pivots (1-13) has absolute scale (rectangle #0, 1, and so on), and another relative scale that is the set of all the planes and location relative to reference (such as centroid as indicated by the large circle #9). Each location may be locked independently to any arbitrary or a specific pivot point based on the subject geometry. The points on torso may be locked to shoulder points or centroid in a given posture, but those on shins may be locked to ankle or knee points. As an example, a point on torso, in Supine position, may be locked to centroid. The indicated co-ordinate may be referenced as <Posture=Supine, Ref=#9, <x=12, y=33>. Inside every posture only a single subset, e.g. a subset of maxima (high pressure points) is necessary to define an alignment marker(s). These high pressure areas correspond to body skeletal structure and the current posture. Sensor array is typically an array of 64×32=2048 sensors, or 128×64=8192 (8K) sensors. Each plane is formed by a distinct posture, the 4 basic postures are Prone, Supine, Left, Right or intermediate postures (such as Left Tilt, Right Tilt, etc.). When a person lies on the sheet sensor, a subset of these values correspond to the actual area in contact with the sensor, refer to FIG. 5. This assembly of data yields one posture and can create a co-ordinate system such that every sensor in this posture can be numbered (uniquely). By using, a 3D representation of human body, an absolute co-ordinate system (a 3D object with uniformly spaced lines parallel to each other in vertical, and horizontal direction. Each square (formed by intersection) can be an absolute co-ordinate (a unique number).

The relative numbers from the posture are used to determine where the pressure sensor values are assigned on the absolute co-ordinate system. By using a pressure signature of the reference and aligning the current pressure signature, since the posture is known, a complete map is assembled. This coordinate system allows us the attachment of various kinds of metadata, associated with that body part. FIG. 6 depicts physical manifestation, in this form the metadata tags/icons/pictures is depicted on the 3D/2D representation of the human body, or other objects, as well as pressure maps of the sensor(s). This metadata can be documents, texts, emails, multimedia data such as voice, pictures, videos, etc. for the various interested parties to interact on. This increases the ease with which the caregivers/users can interact on relative human body points. FIG. 6 shows an example of co-ordinate system use and meta data attachment on location for easier interchange of information. The coordinate marker could be relative to any or all of the alignment pivots, including the centroid or alignment line itself. Such a relative locator is immensely useful in identifying body parts as well. This body co-ordinate system embodiment allows us to use identify the locations on different occasions and in multiple postures as the body planes can overlap. Using the signature (which could be a subset of maxima), the posture is aligned with the reference frames that are related to the 3D model co-ordinate system.

In a system of posture, the postures represent the pressure incident on the human body, see FIG. 5. A 3 dimensional human shape can be built based on set of postures such that entire body is covered. Partial renderings of the 3 dimensional human contour can be used, but as the individual postures cycle to give complete coverage, full reconstruction of the 3 dimensional human shape is achieved for display and monitoring purpose.

In the system, the raw signal is captured for subjects on a sheet sensor capable of capturing pressure incident on the subject. This signal is represented as a matrix [S_{raw}]_{m×n}, which is then subjected to calibration, denoising and other preprocessing. Then, the maxima(s) and minima(s) are identified for each row of the matrix, as shown in FIG. 3. FIG. 3 depicts the signature extraction from those extrema using centroid even though extrema may function as a signature.

The geometry of the sensor array has a predetermined orientation, relative and absolute distances and hence the sensor spacing is known for each individual sensor. Using the array positioning as a Cartesian co-ordinate system, the locations for each of the points is mapped and individual computed, i.e. the points and distances {a, b, c, d, e, f, g, h, i, j}. For every input frame, each value is measured using simple Euclidean distance to determine similarity and the orientation of the body is computed. Using the data, this system can determine identity, postures, and mapping the pressure values to human body.

Similarly, the points to the human body can be mapped by aligning the pivot points on the input frame to the pivot points of template (of the matching posture), this will map and compare all the points on to the human body in absolute terms or relative to the template.

Any signature disclosed can be calculated by a plurality of methods, e.g. Calculate all extrema, calculate a reference such as the centroid or the inclination line running through the centroid.

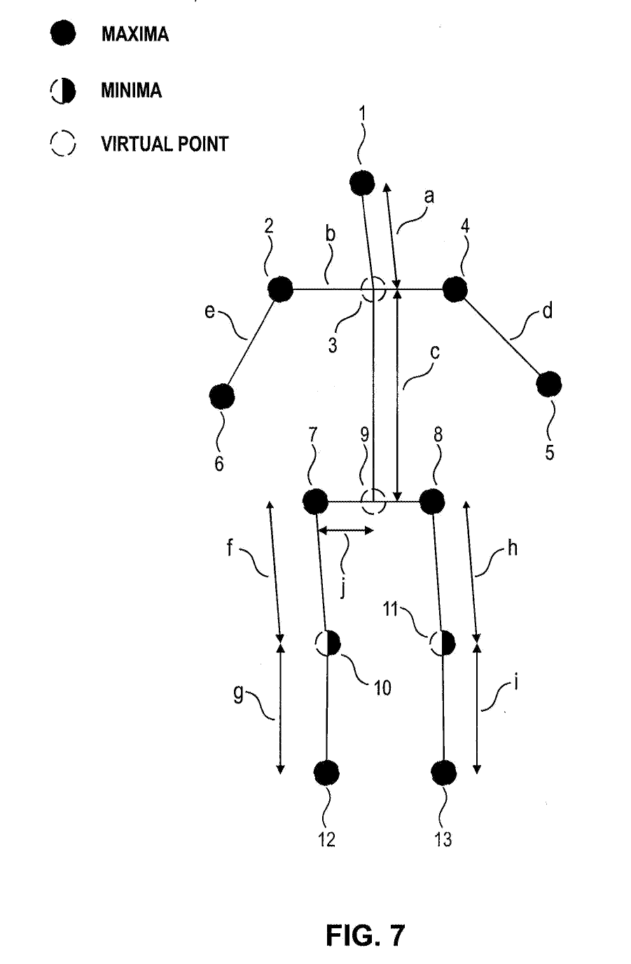

Referring to FIG. 8, the sensor array described above may be located in a piezo-resistive fabric having sensors disposed therein that are typically connected by conductive fibers or wires. A wearable sensor is formed by using following components:
1. A plurality of conductive threads/lines f₁, f₂.
2. A first stitch in the sensor material formed by simple running stitches going over and under the conductive line(s) f₁, f₂ at the desired pitch
3. A second stitch formed in a perpendicular axis to the first stitch and placed on the opposite side of the first stitch and in the perpendicular direction thereto (In general, it can be any angle including being parallel to the first stitch). The intersection between the first and second conductive lines forms a sensor 1, 2. The pitch is controlled by controlling the width of the conductive thread/line, controlling the number of threads in contact with each other in any one direction, or controlling the effective contact area of the sensor 1, 2 by controlling the number of threads intersecting to form the sensor. The stitches need not be straight lines, they can be zig-zag or any arbitrary stitch. Optionally, a thread may be chosen so that only the thread on the top surface is conductive, and the thread going through the piezo resistive fabric layer has a conductive core and insulating top layer. Furthermore, such a thread can be constructed by covering a conductive thread f₁, f_{z} with nonconductive covering that can be stripped off at the desired contact points.
4. A single thread line crosses the layers' plane at every stitch. This orientation may be assembled without crossing the layers, if the conductive thread is glued in place with conductive glue or with and overlay stitch.

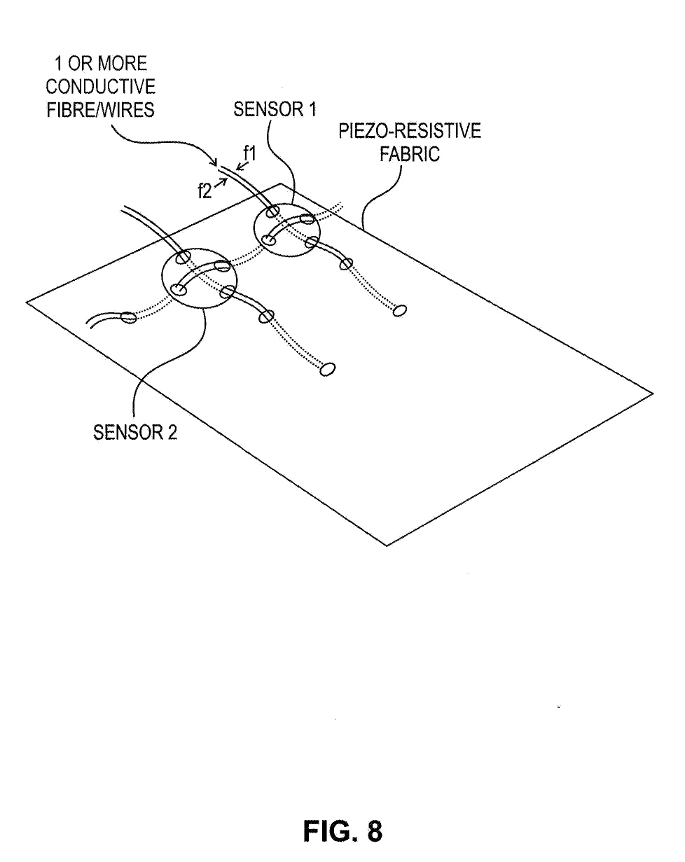

Referring to FIG. 9, a plurality of sensors formed in a piezo resistive fabric formed by the intersection of two conductive lines labeled. At each intersection a sensor is formed. The combination of sensors thus created form an array. Data may be collected individually from Sensor 1, Sensor 2, and any additional plurality of sensors formed by the intersection of two additions separate or conductive lines, as long as the intersection is unique as well as from the piezo resistive fabric. The material in which the sensor array is formed may be flexible or static. Although, for a wearable embodiment of the sensor assembly a flexible fabric is preferred.

Furthermore, the relative and absolute orientation of individual sensors in the array can form a representation of the human body, including separate limbs, core components of the torso, or essentially any element of the anatomy or physiology that would adventitiously feature placement of a sensor for data collection.

The sensor array formed in FIG. 8 also yields a series of continuous sensors, especially in fabric or similar flexible materials for wearable sensors. The array creates a pre-selected arbitrary topology and can use both volume electrical characteristics (resistance, capacitance, or inductance) or surface electrical characteristics (resistance) to generate data or detect changes in, for example, the motion, position or other characteristic of a person wearing a sensor array.

Alternate Embodiment of Improving Classical Pressure Sensor.

A classical pressure sensor as in US 2012/0323501 A1 (See FIG. 9) typically depends on uniformity of the piezo sensitive material to implement a repeatable sensor. The various variables such as volume resistance, surface resistance, etc. In practice, it is difficult to achieve high degree of uniformity with the piezo sensitive materials especially over large areas. Additionally, this sensor is prone to hot spots on account of material fatigue, etc. This embodiment improves the classical pressure sensor uniformity and the longevity and repeatability of this classical sensor. A multilayer arrangement for the PIEZO sensitive material is used. Rows are numbered R1 to Rn, Columns are numbered C1 to Cm, and the layers are numbered L1 to Lr, where n, m and r are arbitrary integers denoting the count of each item. These multiple piezo-electric layers drastically improve the practical performance of the sensor. It allows us to choose multiple layers each of which can be optimized for the desired characteristic. For example, if we desire high surface resistance, but the preferred volume resistance does not lend itself to reasonable fabrication, additional sheets are added with high surface resistance, and together this sandwich will yield the desired characteristic.

The invention further includes a method for decoupling the sensor array data. This decoupling method dramatically improves the quality of the sensor readings and greatly improves the utility of the sensor array.

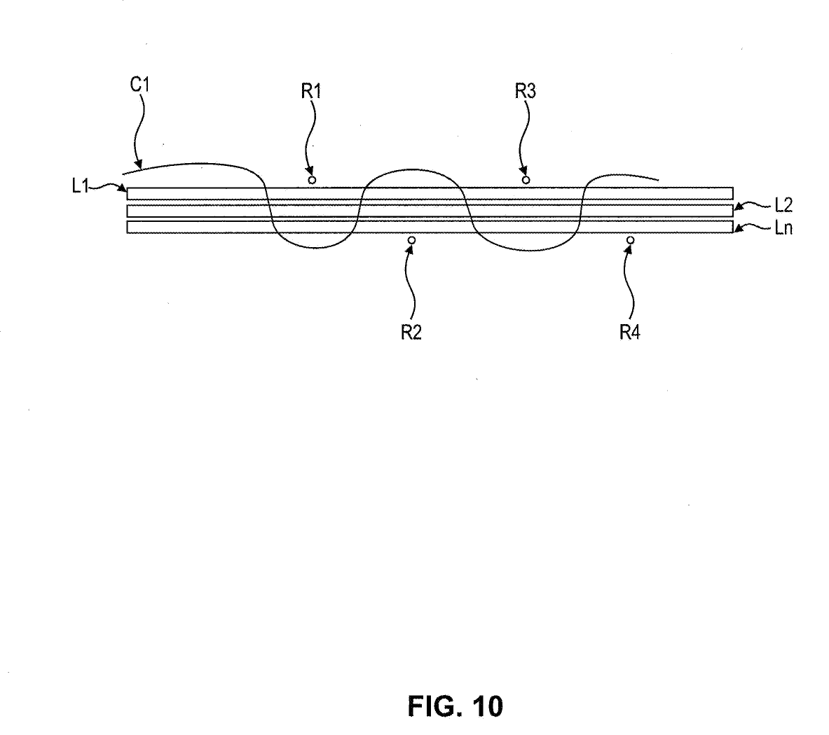

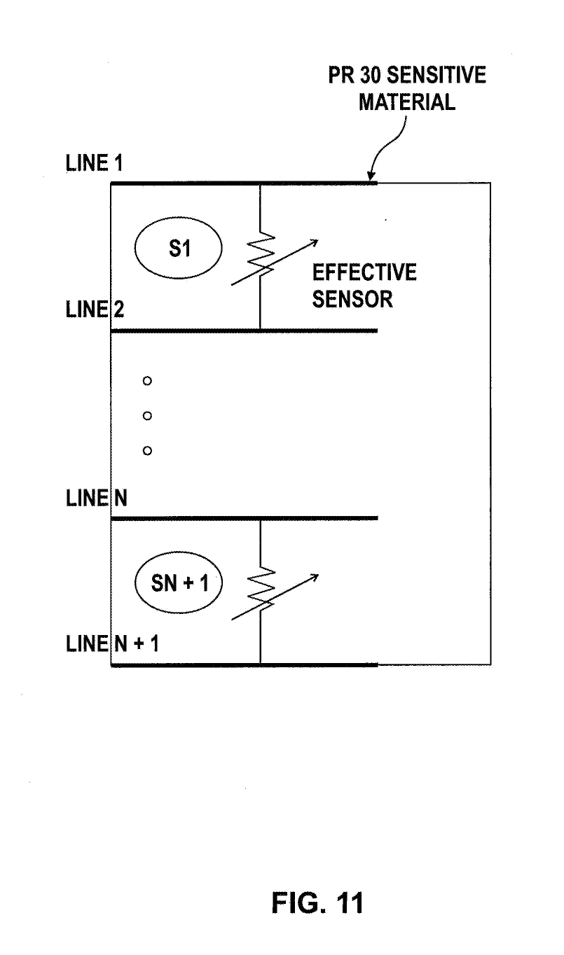

The preferred embodiment of the sensor array is represented by FIG. 12A. The Figure displays two sets of conductive strips. Suitable conductive materials are described in more detail in “Fabric-based Pressure Sensor Arrays and Methods for Data Analysis,” Pub. No. US-2012-0323501-A1. Although FIG. 12A contains two sets of vertical and two sets of horizontal conductive strips, the sensor array may comprise an arbitrary number of rows and columns. Additionally, the strips need not be orthogonal to each other, and may in fact be arranged in any suitable pattern. In this example, piezoresistive sensors are located at the intersections of the strips. The decoupling method is not limited to piezoresistive sensors, however, and the sensor elements may transduce any physical quantity, such as temperature, pressure, or moisture. It is even possible for different sensor elements in the same array to sense different quantities; e.g., some sensing pressure while others sense moisture.

The resistance of the sensor elements is represented by r_{rc} The circuit further includes an analog to digital convertor (“ADC”) capable of measuring voltage potential. A row is selected by applying a reference voltage (v_{ref}) to it, and a column is selected by connecting it to an ADC for measurement of its potential. Optionally, every row, every column, or both may be connected to a grounded pull-down resistor (r_{PR} & r_{PC}). Optionally, a grounded offset resistor (r_{off}) may be connected in parallel to the ADC. If none is present, the ADC effectively measures across a column pull-down resistor instead.

This continuous sensor array reads a sensor element by addressing its row and column, rather than running a dedicated line to each individual sensor element as in a discrete array. Such a design can be more compact, cost-effective, and robust than a discrete array. However, without further processing, the value sampled by this arrangement less accurately reflects the underlying physical quantity it is intended to measure.

The problem is that the sampled quantity does not directly correspond to only the quantity transduced by the selected sensor element. Rather, it is affected by all the other sensor elements in a complex way. The fact that multiple sensors share the same conductive strips results in unwanted electrical interference between the sensors. The combined effect of the interplay of all other sensor elements along with pull-down resistors is referred to as “coupling”. There are methods, however, that allow the desired sensor element value to be recovered and the unwanted interference to be removed (“decoupling”).

When reading with a small offset resistor, the dominant problem is “phantoms” resulting from backward shunt currents, as illustrated in FIG. 12B. The shunt current shown in FIG. 12B passing through the resistors at three corners of a rectangle (r₃₀, r₃₃, and r₀₃) distorts the measurement of sensor r₀₀. With even a modestly large numbers of rows and columns, the noise from this coupling effect will be many times larger than the original signal. Accordingly, the coupling effect produces a “phantom” change in voltage near the r₀₀ sensor. Unless corrected, this makes it practically impossible to accurately measure the resistance at r₀₀ Placing a diode at every sensor to block unwanted shunt currents does effectively cut off the shunt currents. But this solution is undesirable because it greatly increases the complexity of the sensor array device.

Additionally, the use of pull-down resistors distorts the readings of the sensor values. The cumulative effect of even a modestly large number of them will be significant. These pull-down resistors must therefore be accounted for in attempting to reconstruct the decoupled signal.

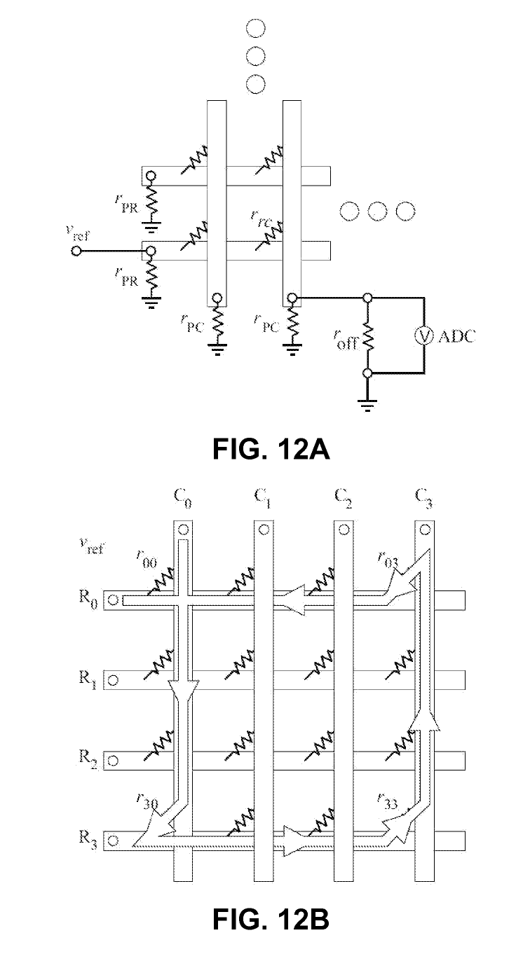

FIG. 13 further shows the coupling effects on a sample 16×32 image. The leftmost image is the original image. The next image to the right is a coupled image using only pull-down resistors. Adding offset resistors further decreases quality. The next image on the right is from an array using 10 kΩ offset resistors and 100 kΩ pull-down resistors. The rightmost image shows the distortion when only offset resistors are used.

The decoupling technique requires sampling all the sensor elements while holding the underlying element resistances constant. Preferably, the sampling and decoupling are performed in two distinct steps. First, the system rapidly scans the entire sensor array to capture raw data one frame at a time. The system then performs the decoupling and further processing in a second distinct step.

The decoupling process, detailed below, may be executed either by specialized hardware or in software on a general-purpose processor, and either on the acquisition device itself or on a separate device with greater computational power. The general-purpose processor may be part of a desktop computer, laptop computer, mobile telephone, or a tablet computer. This list is not exhaustive and other computers may be used. As the decoupling process demands a great deal of computational power, standard mathematical and computational techniques are applied to maximize its efficiency.

The decoupling process depends fundamentally on a coupling model, derived by assuming an ideal sensor circuit as shown in FIG. 12A. In this model, capacitance and inductance of the circuit are assumed to be negligible. G is a matrix with an entry, g_{rc}, corresponding to each sensor in the array. Let g_{rc} be the conductance of the sensor element at row r and column c divided by the conductance across the ADC (g_{off}+g_{PC}). Further, A is a matrix with entries a_{rc}. Let a_{rc} be the voltage measured across the ADC when selecting that row and column divided by the reference voltage. The coupling model relates G to A.

The solution, according to this coupling model, giving A in terms of G for the general case, can be expressed as follows. First, where g_{pc} is the conductance of the pull-down resistors r_{PC}, let:

$${p}_{c} = {g}_{PC} + {\sum }_{r}^{ } {g}_{rc}$$

Where g_{PR} is the conductance of the pull-down resistors r_{PR}, let:

$$\text{?} = {g}_{PR} + {\sum }_{c}^{ } {g}_{rc}$$

$$\text{?} \text{indicates text missing or illegible when filed}$$

Further let gᵣ be the vector formed from row r of the conductance matrix G. Please note that qᵣ⁻¹ is the reciprocal of qᵣ. Then let the matrix Ψ be equal to:

$$Ψ = diag p - {\sum }_{r}^{ } {q}_{r}^{- 1} {g}_{r} {g}_{r}^{T}$$

If Ω is the inverse of Ψ, then we may define a matrix S as the product of G and Ω. Computing S may be performed efficiently by in-place Cholesky decomposition.

Ω−Ψ⁻¹

S=GΩ

Each entry of A, α_{yx}, may be found by performing the following calculations. The variable y denotes a row and x denotes a column. Let ω represent the entries of Ω. Please note that q_{y}⁻¹ is the reciprocal of q_{y}.

$${z}_{y} = \frac{1}{1 + {q}_{y}^{- 1} {g}_{y} \cdot {s}_{y}}$$

$${a}_{yx} = \frac{{z}_{y} {s}_{yz}}{1 + {g}_{off} ( {ω}_{xx} - {q}_{y}^{- 1} {z}_{y} \text{?} )}$$

$$\text{?} \text{indicates text missing or illegible when filed}$$

In the case where there is no offset resistor, the computation can be simplified:

a_{y}=z_{y}s_{y}

In the case of no pull-down resistors, the above solution encounters a singularity, but an alternative slower calculation may be used. Let φ_{y} represent the entries of Φ_{y}.

$${Φ}_{y} = {( Ψ + {q}_{y}^{- 1} {g}_{y} {g}_{y}^{T} )}^{- 1}$$

$${a}_{yx} = \text{?}$$

$$\text{?} \text{indicates text missing or illegible when filed}$$

The desired quantity is ultimately G, the conductance of the sensors. G may be obtained by sampling A. Since direct computation is impractical, the technique is iterative. First, a candidate solution for G is obtained. Using the coupling model and the candidate solution G, a predictive matrix A is generated. After directly sampling the sensor array, the real value of A is compared with the predicted value. If the difference between the two matrices is small enough, the candidate solution G is accepted as the solution. Otherwise, G is refined by the following iterative process.

The iterative process uses the coupled image F, where each element f_{rc} of F is straightforwardly related to the measured a_{rc} by:

$$f = \frac{a}{1 - a}$$

F is a representation of the coupled image. G is the non-coupled conductance image. Using the coupling model as described above, it is possible to create a coupled conductance function (7G) for a given non-coupled conductance image G. That is, there is a function C(G) such that F equals C(G).

The starting point of the iterative process is to scale F so that coupling yields the same sum of elements. The sum of the absolute value of each entry within the F matrix is denoted by ∥F∥₁, and likewise, the sum of the absolute value of each entry within the C(F) matrix is ∥C(F)∥₁. A parameter α may be tuned to optimize convergence. How to tune α will vary on the circumstances and application. In the simplest case, α is set equal to one.

$${G}_{0} = α \frac{{‖ F ‖}_{1}}{{‖ C ( F ) ‖}_{1}} F$$

Subsequent iterations of G are computed in the following way, essentially subtracting out the scaled difference from the expected result:

$${G}_{i + 1} = {G}_{i} + β \frac{{‖ {G}_{i} ‖}_{1}}{{‖ F ‖}_{1}} ( F - C ( {G}_{i} ) )$$

The parameter β may be one in the simplest case, or it may be selected to emphasize either speed or the likelihood of convergence. β closer to zero will converge more slowly but will reduce the risk that G fails to converge to a suitable value. If any individual iteration overshoots too far, yielding a result that moves farther away rather than closer, that iteration may be modified with successively smaller values for β (e.g., cut in half each time) until that is no longer the case.

Convergence can be considered complete, the iterative process terminated, and Gᵢ accepted as the solution, when C(Gᵢ) is sufficiently close to F by some measure. That is, a tolerance e is chosen, whether absolute or some fraction of the magnitude of F, such that a solution is considered acceptable when

∥F−C(Gᵢ)∥₁<ε

In some cases, due to noise, rounding error, or various other causes, the exact solution for G for a given F will contain negative values, which represents a physical impossibility because conductance cannot be negative. There are several ways of addressing this problem. The simplest is to set all negative entries to a non-negative number (such as zero) after completing the final iteration of Gᵢ₊₁. Another method, which may yield truer results, is to set all negative entries to a non-negative number (such as zero) after each iteration. Since this may prevent full convergence, the convergence criteria may be adjusted accordingly to stop computing iterations when further progress from computing iterations starts becoming too small.

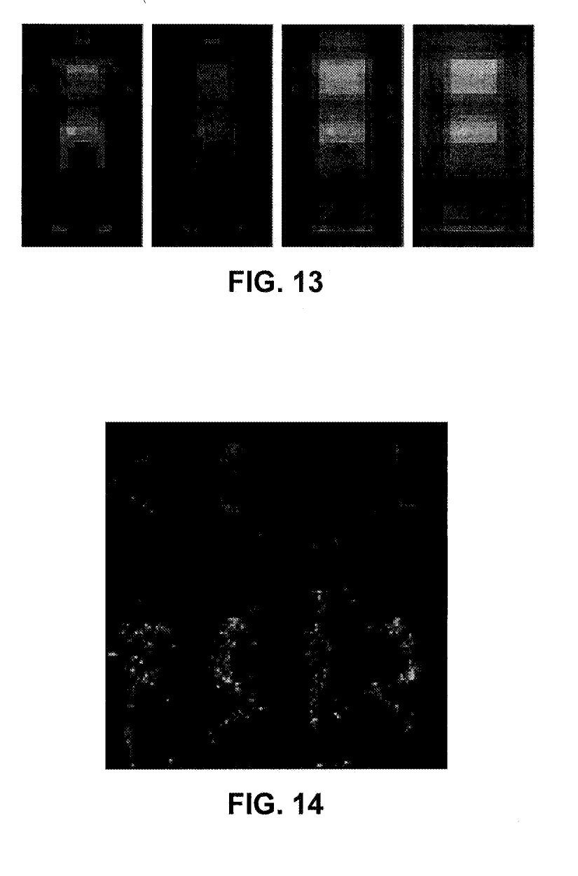

FIG. 14 shows the improvement in image quality the decoupling technique may achieve. FIG. 14 shows images from a pressure sensor array on a human body. The array has 32 by 64 sensors and uses 1 kΩ offset and 100 kΩ pull-down resistors. The images from the upper row are raw images before decoupling. The images in the bottom row are the results after decoupling.

1. A pressure sensing array system comprising:
a plurality of sensors forming an array, wherein the orientation of the array and the sensors are spaced apart in a pre-determined configuration wherein at least a subset of the plurality of sensors forming the array are disposed in a multi-layered material that changes one of resistive properties, capacitive properties, and inductive properties when pressure is applied, and
computing means for data processing of pressure data from the plurality of sensors.

2. The pressure sensing array of claim 1, wherein the pre-determined configuration is non-uniform.

3. The pressure sensing array of claim 1, further comprising sensors formed from an intersection of conducting lines, wherein a first set and a second set of conducting lines form a plurality of sensors of the array.

4. The pressure sensing array of claim 3, wherein the plurality of sensors are oriented in an assembly in which columns or rows cross a layer of the material at a plurality of points.

5. The pressure sensing array of claim 1, wherein at least a subset of the plurality of sensors forming the array are disposed in a multi-layered material that changes one of resistive properties, capacitive properties, and inductive properties when pressure is applied.

6. The pressure sensing array of claim 1, wherein the connection between the sensors and the computing means is comprised of a wireless connection.

7. The pressure sensing array of claim 1, wherein the plurality of sensors is disposed in a multilayered piezoresistive material.

8. The pressure sensing array of claim 7, wherein the multi-layered material has an upper and a lower surface and conductive lines comprising the sensors traverse the upper and lower layers of the material.

9. A method of assessing a position of an object using a pressure sensing array comprising:
providing a pressure sensing array comprising a plurality of spaced apart sensors, wherein the orientation of the plurality of sensors yields a three dimensional representation of the object;
sensing a pressure value from the plurality of sensors;
correlating the pressure value received from each sensor with a position of the sensor in the array;
generating a pressure signature comprised of data from the array to assess the position of the object.

10. The method of claim 9, wherein the signature determines biometric identity.

11. The method of claim 9, wherein the signature is a posture of a human form.

12. The method of claim 9 wherein the sensing data is comprised of a co-ordinate system formed by using postures of a human body as body planes, and dominant body features as pivot points.

13. The method of claim 9 wherein the sensing data is comprised of a co-ordinate system used to track pressure points on the human body.

14. The method of claim 9 wherein the signature is comprised of a visual representation of meta-data for the human form, allowing user interaction with the meta-data for a location on the body.

15. The method of claim 9, further including decoupling the data obtained from one or more sensors in the array.

16. The method of claim 15, wherein the step of decoupling the data comprises generating a prediction of the conductance of one or more sensors in the sensor array.

17. The method of claim 16, wherein the step of decoupling the data further comprises updating the prediction.

18. The method of claim 17, wherein the step of updating the prediction comprises performing the following calculation:
$${G}_{i + 1} = {G}_{i} + β \frac{{‖ {G}_{i} ‖}_{1}}{{‖ F ‖}_{1}} ( F - C ( {G}_{i} ) )$$

19. The method of claim 17, wherein the step of updating the prediction comprises generating a prediction of the voltage difference across one or more sensors in the sensor array, generating a measurement of the voltage difference across one or more sensors in the sensor array, and comparing the prediction of the voltage difference and the measurement of the voltage difference.

20. The method of claim 19, wherein the step of generating a prediction of the voltage difference comprises generating a matrix with y rows and x columns, where the entries of the matrix are:
$${a}_{yx} = \frac{{z}_{y} {s}_{yx}}{1 \text{?} {g}_{off} ( {ω}_{xx} \text{?} {q}_{y}^{- 1} \text{?} \text{?} )}$$
$$\text{?} \text{indicates text missing or illegible when filed}$$

21. The method of claim 19, wherein the step of generating a prediction of the voltage difference comprises generating a matrix with y rows and x columns, where the entries of the matrix are:
$${a}_{yx} = \text{?}$$
$$\text{?} \text{indicates text missing or illegible when filed}$$
